(19) United States
(12) Patent Application Publication
(10) Pub. No.: US 2022/0120789 A1
(43) Pub. Date: Apr. 21, 2022

(54) CURRENT DETECTION APPARATUS AND CONTROLLER FOR AC ROTARY MACHINE

(71) Applicant: Mitsubishi Electric Corporation, Tokyo (JP)

(72) Inventor: Akira FURUKAWA, Tokyo (JP)

(73) Assignee: Mitsubishi Electric Corporation, Tokyo (JP)

(21) Appl. No.: 17/394,502

(22) Filed: Aug. 5, 2021

(30) Foreign Application Priority Data
Oct. 21, 2020 (JP) 2020-176437

(51) Int. Cl. G01R 15/20; G01R 33/038; G01R 31/34

(52) U.S. Cl. CPC G01R 15/20; G01R 31/34; G01R 33/038

(57) ABSTRACT

In a current detection apparatus which detects current flowing through the armature windings of plural phases of plural sets using each magnetic sensor which is disposed at a position the magnetic flux radially emitted from the rotor crosses, to provide a current detection apparatus which can suppress that the control accuracy of output torque is deteriorated by the current detection error which occurs due to the magnetic flux of the rotor. A current detection apparatus, wherein in each set, the magnetic sensors of n-phase are disposed so that an absolute value of a detection component of a rotor flux density which is a component of flux density of the rotor detected by the magnetic sensor of each phase become equal with each other.

### INCORPORATION BY REFERENCE

The disclosure of Japanese Patent Application No. 2020-176437 filed on Oct. 21, 2020 including its specification, claims and drawings, is incorporated herein by reference in its entirety.

### BACKGROUND

The present disclosure relates to a current detection apparatus and a controller for AC rotary machine.

For example, there is a current detection apparatus which detects the current of the winding of each phase of the AC rotary machine which has two sets of three-phase windings using the magnetic sensor. However, the disturbance magnetic flux due to the current of other phases may mix in the magnetic sensor of each phase, and the current detection error may occur. Various configurations for reducing this error has been proposed.

For example, in the current detection apparatus described in JP 2018-96795 A, the current path of one phase is formed in the U-shaped, the first magnetic sensor and the second magnetic sensor are disposed at the first opposite portion and the second opposite portion whose current directions become opposite with each other, and the current detection error which occurs due to the disturbance magnetic flux is reduced.

### SUMMARY

However, in the technology of JP 2018-96795 A, in order to detect the current of one phase, two magnetic sensors are required. For example, in the case of the AC rotary machine which has two sets of three-phase windings, since twelve magnetic sensors are required, compared with the case where one magnetic sensor detects the current of each phase, cost increases and the apparatus is enlarged.

Like the Lundell type rotor, the axial direction one side part of the rotor becomes N pole or S pole, if each magnetic sensor is disposed on the axial direction one side of the rotor, the magnetic flux radially emitted from the rotor in the radial direction crosses each magnetic sensor. Due to this magnetic flux of the rotor, the current detection error may occur in each magnetic sensor.

Then, in a current detection apparatus which detects current flowing through the armature windings of plural-phase of plural sets using each magnetic sensor which is disposed at a position where the magnetic flux radially emitted from the rotor crosses, the purpose of the present disclosure is to provide a current detection apparatus which can suppress that the control accuracy of output torque is deteriorated by the current detection error which occurs due to the magnetic flux of the rotor.

A current detection apparatus according to the present disclosure is a current detection apparatus of an AC rotary machine which is provided with a rotor and a stator having m sets of n-phase armature windings (m is an integer greater than or equal to 1, and n is an integer greater than or equal to 3), the current detection apparatus including:

m sets of n-phase magnetic sensors each of which is disposed opposite to a connection line of each phase of each set supplying current to the armature winding of each phase of each set; and an armature current detection unit which detects a current which flows into the armature winding of each phase of each set, based on an output signal of the magnetic sensor of each phase of each set, wherein the magnetic sensor of each phase of each set is disposed at a position where a magnetic flux radially emitted from the rotor in a radial direction crosses, and in each set, the magnetic sensors of n-phase are disposed so that an absolute value of a detection component of a rotor flux density which is a component of flux density of the rotor detected by the magnetic sensor of each phase become equal with each other.

A current detection apparatus according to the present disclosure is a current detection apparatus of an AC rotary machine which is provided with a rotor having a field winding and a stator having m sets of n-phase armature windings (m is an integer greater than or equal to 1, and n is an integer greater than or equal to 2), the current detection apparatus including:

m sets of n-phase magnetic sensors each of which is disposed opposite to a current path flowing current of the armature winding of each phase of each set; and

an armature current detection unit which detects a current which flows into the armature winding of each phase of each set, based on an output signal of the magnetic sensor of each phase of each set,

wherein the magnetic sensor of each phase of each set is disposed at a position where a magnetic flux radially emitted from the rotor in a radial direction crosses,

wherein the armature current detection unit, about each phase of each set, calculates a current error value corresponding to an error component of the current detection value which is generated by the magnetic flux of the rotor which crosses the magnetic sensor, based on a field current which flows through the field winding; and

corrects the current detection value of each phase of each set by the current error value of each phase of each set, and

wherein about each phase of each set, by referring to an error calculation function in which a relationship between the field current and the current error value is preliminarily set, the armature current detection unit calculates the current error value corresponding to the present field current.

A controller for AC rotary machine according to the present disclosure provided with the current detection apparatus including:

an armature current control unit that calculates an armature current command value which is a current command value of the armature winding, calculates an armature voltage command value based on the armature current command value and the current detection value of the armature winding detected by the current detection apparatus, and applies voltage to the armature winding by controlling on/off a switching device which an inverter has based on the armature voltage command value, and

a field current control unit that calculates a field current command value which is a current command value of the field winding, and applies voltage to the field winding by controlling on/off a switching device which a converter has based on the field current command value,

wherein a response time constant of a control system from the field current command value to a field current which flows through the field winding is larger than a response time constant of a control system from the armature current command value to an armature winding current.

In the d-axis and q-axis current detection values of each set, the detection error component of each phase due to the magnetic flux of the rotor is canceled with each other, and can be reduced; and the d-axis and q-axis current detection values of each set can be brought close to the d-axis and q-axis true currents of each set. Accordingly, the control accuracy of output torque can be improved.

### BRIEF DESCRIPTION OF THE DRAWINGS

FIG. 1 is a schematic configuration diagram of the AC rotary machine and the controller according to Embodiment 1;

FIG. 2 is a figure for explaining the phase of the armature windings according to Embodiment 1;

FIG. 3 is a schematic block diagram of the controller according to Embodiment 1;

FIG. 4 a figure for explaining arrangement of the magnetic sensors according to Embodiment 1;

FIG. 5 is a perspective view of the Lundell type rotor according to Embodiment 1;

FIG. 6 is a schematic cross-sectional view of the AC rotary machine according to Embodiment 1;

FIG. 7 a figure for explaining arrangement of the magnetic sensors according to Embodiment 1;

FIG. 8 is a figure for explaining the magnetic flux detected by the magnetic sensor according to Embodiment 1;

FIG. 9 is a figure for explaining the magnetic sensor provided with the magnetic-flux collecting core according to Embodiment 1;

FIG. 10 a figure for explaining arrangement of the magnetic sensors according to Embodiment 1;

FIG. 11 is a figure explaining the relationship between the field current and the magnetic flux of the rotor according to Embodiment 2;

FIG. 12 a figure for explaining arrangement of the magnetic sensors according to Embodiment 3;

FIG. 13 a figure for explaining arrangement of the magnetic sensors according to Embodiment 4; and

FIG. 14 is a hardware configuration diagram of the controller according to Embodiment 1.

### DETAILED DESCRIPTION OF THE EMBODIMENTS

### 1. Embodiment 1

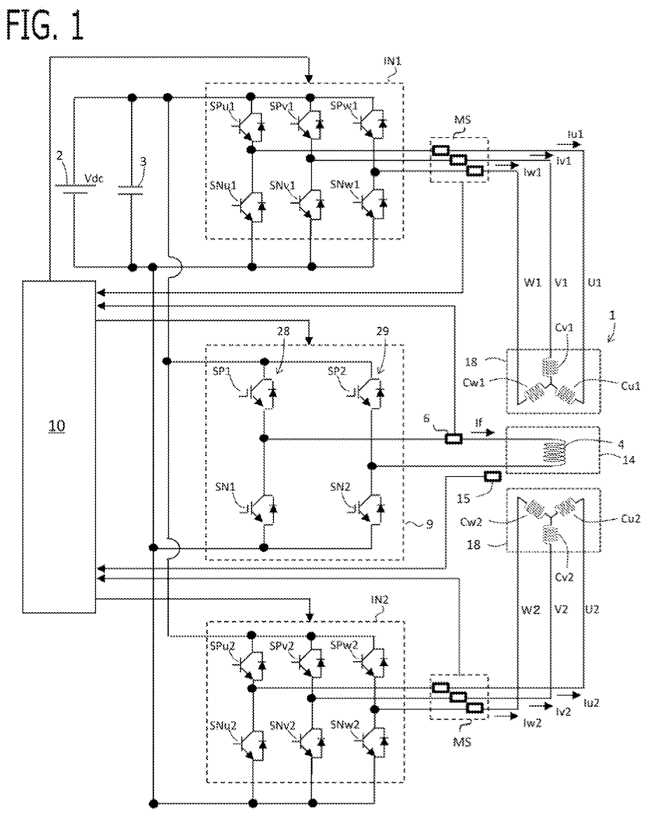

The current detection apparatus according to Embodiment 1 is explained with reference to drawings. FIG. 1 is a schematic configuration diagram of the AC rotary machine 1 and the controller 10 according to the present embodiment. The current detection apparatus is built into the AC rotary machine 1 and the controller 10.

### 1-1. AC Rotary Machine 1

The AC rotary machine 1 is provided with a stator 18 and a rotor 14 disposed on the radial-direction inner side of the stator 18. m sets of n-phase armature windings (m is an integer greater than or equal to 1, and n is an integer greater than or equal to 3) are wound around an iron core of the stator 18. In the present embodiment, m is set to 2 and n is set to 3. That is to say, the stator 18 is provided with the first set of the armature windings Cu1, Cv1, Cw1 of three-phase of U1 phase, V1 phase, and W1 phase, and the second set of the armature windings Cu2, Cv2, Cw2 of three-phase of U2 phase, V2 phase, and W2 phase. The armature windings of three-phase of each set may be connected by star connection, or may be connected by delta connection.

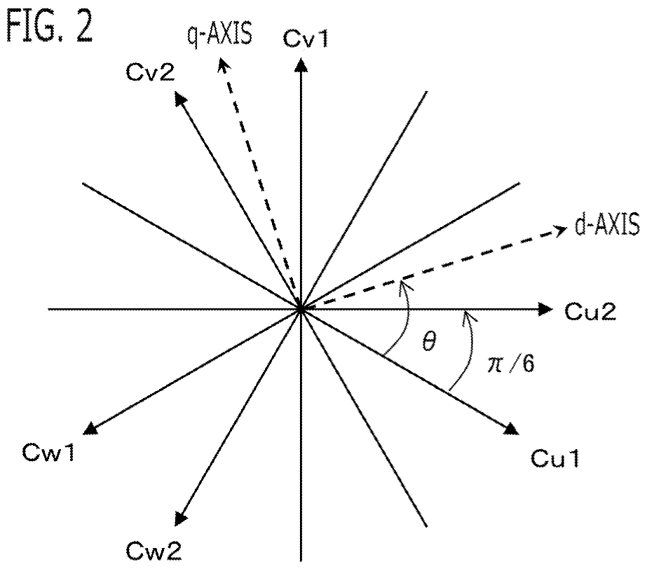

In the present embodiment, as a schematic diagram is shown in FIG. 2, a phase difference A in an electrical angle of the position of the second set of three-phase armature windings Cu2, Cv2, Cw2 with respect to the position of the first set of three-phase armature windings Cu1, Cv1, Cw1 is set to Δθ=−π/6 (−30 degrees). The electrical angle becomes an angle obtained by multiplying the number of pole groups of the magnet to the mechanical angle of the rotor 14.

The rotor 14 is provided with a magnet. In the present embodiment, a field winding 4 is wound around an iron core of the rotor 14, and the magnet of the rotor 14 is a magnet in which a field is generated by the field winding. Accordingly, the AC rotary machine 1 is a field winding type synchronous rotary machine. The magnet of the rotor 14 may be a permanent magnet.

A rotation sensor 15 which detects a rotational angle (a magnetic pole position) of the rotor 14 is provided in the rotor 14. An output signal of the rotation sensor 15 is inputted into the controller 10. Various kinds of sensors, such as a Hall element, a resolver, or an encoder, are used for the rotation sensor 15. The rotation sensor 15 may be not provided, and the rotational angle (the magnetic pole position) may be estimated based on current information which are obtained by superimposing a harmonic wave component on the current command value describes below (so-called, sensorless system).

### 1-2. DC Power Source 2

The DC power source 2 outputs a DC voltage Vdc to the first set of inverter IN1, the second set of inverter IN2, and the converter 9. As the DC power source 2, any apparatus which outputs DC voltage, such as a battery, a DC-DC converter, a diode rectifier, and a PWM rectifier, is used. A smoothing capacitor 3 is connected in parallel to the DC power source 2.

### 1-3. Inverter

The first set of inverter IN1 performs power conversion between the DC power source 2 and the first set of three-phase armature windings. The second set of inverter IN2 performs power conversion between the DC power source 2 and the second set of three-phase armature windings.

The first set of inverter IN1 is provided with three of a series circuit where a positive electrode side switching device SP1 connected to the positive electrode side of the DC power source 2 and a negative electrode side switching device SN1 connected to the negative electrode side of the DC power source 2 are connected in series, corresponding to respective phase of the first set of three-phase armature windings. A connection node of two switching devices in each series circuit is connected to the first set of armature winding of the corresponding phase.

Specifically, in the first set of the series circuit of U phase, the positive electrode side switching device SPu1 of U phase and the negative electrode side switching device SNu1 of U phase are connected in series, and the connection node of two switching devices is connected to the first set of the coil Cu1 of U phase. In the first set of the series circuit of V phase, the positive electrode side switching device SPv1 of V phase and the negative electrode side switching device SNv1 of V phase are connected in series, and the connection node of two switching devices is connected to the first set of the coil Cv1 of V phase. In the first set of the series circuit of W phase, the positive electrode side switching device SPw1 of W phase and the negative electrode side switching device SNw1 of W phase are connected in series, and the connection node of two switching devices is connected to the first set of the coil Cw1 of W phase.

The second set of inverter IN2 is provided with three of a series circuit where a positive electrode side switching device SP2 connected to the positive electrode side of the DC power source 2 and a negative electrode side switching device SN2 connected to the negative electrode side of the DC power source 2 are connected in series, corresponding to respective phase of the second set of three-phase armature windings. A connection node of two switching devices in each series circuit is connected to the second set of armature winding of the corresponding phase.

Specifically, in the second set of the series circuit of U phase, the positive electrode side switching device SPu2 of U phase and the negative electrode side switching device SNu2 of U phase are connected in series, and the connection node of two switching devices is connected to the second set of the coil Cu2 of U phase. In the second set of the series circuit of V phase, the positive electrode side switching device SPv2 of V phase and the negative electrode side switching device SNv2 of V phase are connected in series, and the connection node of two switching devices is connected to the second set of the coil Cv2 of V phase. In the second set of the series circuit of W phase, the positive electrode side switching device SPw2 of W phase and the negative electrode side switching device SNw2 of W phase are connected in series, and the connection node of two switching devices is connected to the second set of the coil Cw2 of W phase.

IGBT (Insulated Gate Bipolar Transistor) in which a diode is connected in inverse parallel, a bipolar transistor in which a diode is connected in inverse parallel, MOSFET (Metal Oxide Semiconductor Field Effect Transistor), or the like is used for the switching device of the inverter of each set. Agate terminal of each switching device is connected to the controller 10 via a gate drive circuit and the like. The each switching device is turned on or turned off by the switching signal outputted from the controller 10.

### 1-4. Magnetic Sensor MS

A magnetic sensor MS of each phase of each set which detects a current of the armature winding of each phase of each set is provided. The magnetic sensor MS is a Hall element or the like. The one magnetic sensor MS is provided for the armature winding of each phase of each set. The magnetic sensor MS of each phase of each set is disposed opposite to a connection line WR of each phase of each set which supplies current to the armature winding of each phase of each set. Specifically, the magnetic sensor MS is disposed opposite to each of the six connection lines WR which connect between the inverter of each set and the three-phase armature windings of each set. The magnetic sensor MSu1 of U1 phase of first set is disposed opposite to the connection line WRu1 of U1 phase of first set; the magnetic sensor MSv1 of V1 phase of first set is disposed opposite to the connection line WRv1 of V1 phase of first set; and the magnetic sensor MSw1 of W1 phase of first set is disposed opposite to the connection line WRw1 of W1 phase of first set. The magnetic sensor MSu2 of U2 phase of second set is disposed opposite to the connection line WRu2 of U2 phase of second set; the magnetic sensor MSv2 of V2 phase of second set is disposed opposite to the connection line WRv2 of V2 phase of second set; and the magnetic sensor MSw2 of W2 phase of second set is disposed opposite to the connection line WRw2 of W2 phase of second set. The output signal of each magnetic sensor MS is inputted into the controller 10.

### 1-5. Converter 9

The converter 9 has a switching device and performs power conversion between the DC power source 2 and the field winding 4. In the present embodiment, the converter 9 is H bridge circuit which is provided with two of a series circuit where a positive electrode side switching device SP connected to the positive electrode side of the DC power source 2 and a negative electrode side switching device SN connected to the negative electrode side of the DC power source 2 are connected in series. The connection node of the positive electrode side switching device SP1 and the negative electrode side switching device SN1 in the first series circuit 28 is connected to one end of the field winding 4. The connection node of the positive electrode side switching device SP2 and the negative electrode side switching device SN2 in the second series circuit 29 is connected to the other end of the field winding 4.

IGBT in which the diode is connected in inverse parallel, the bipolar transistor in which the diode is connected in inverse parallel, MOSFET, or the like is used for the switching device of the converter 9. A gate terminal of each switching device is connected to the controller 10 via a gate drive circuit and the like. The each switching device is turned on or turned off by the switching signal outputted from the controller 10.

The converters 9 may be other configurations. For example, the negative electrode side switching device SN1 of the first series circuit 28 may be replaced to a diode, and the positive electrode side switching device SP2 of the second series circuit 29 may be replaced to a diode.

A field current sensor 6 is a current detection circuit which detects a field current If which is current flowing through the field winding 4. In the present embodiment, the field current sensor 6 is provided on a wire between the connection node of the first series circuit 28 and one end of the field winding 4. The field current sensor 6 may be provided in other parts which can detect the field current If. The output signal of the field current sensor 6 is inputted into the controller 10. The field current sensor 6 is a current sensor, such as a Hall element, or a shunt resistance.

### 1-6. Controller 10

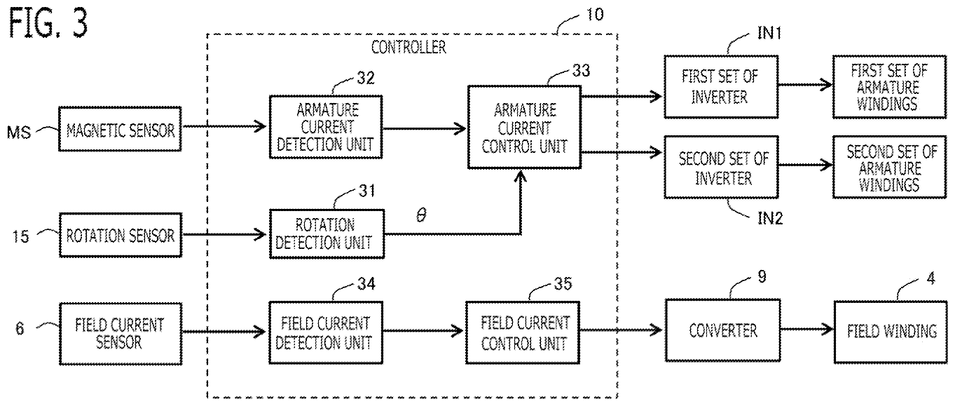

The controller 10 controls the AC rotary machine 1 via the first set and the second set of inverters IN1, IN2, and the converter 9. As shown in FIG. 3, the controller 10 is provided with functional parts of a rotation detection unit 31, an armature current detection unit 32, an armature current control unit 33, a field current detection unit 34, a field current control unit 35, and the like. Each function of the controller 10 is realized by processing circuits provided in the controller 10. Specifically, as illustrated in FIG. 14, the controller 10 is provided with, as processing circuits, an arithmetic processor (computer) 90 such as a CPU (Central Processing Unit), storage apparatuses 91 which exchange data with the arithmetic processor 90, an input circuit 92 which inputs external signals to the arithmetic processor 90, an output circuit 93 which outputs signals from the arithmetic processor 90 to the outside, a communication circuit 94 which performs data communication with external apparatuses, and the like.

As the arithmetic processor 90, ASIC (Application Specific Integrated Circuit), IC (Integrated Circuit), DSP (Digital Signal Processor), FPGA (Field Programmable Gate Array), various kinds of logical circuits, various kinds of signal processing circuits, and the like may be provided. As the arithmetic processor 90, a plurality of the same type ones or the different type ones may be provided, and each processing may be shared and executed. As the storage apparatuses 91, there are provided a RAM (Random Access Memory) which can read data and write data from the arithmetic processor 90, a ROM (Read Only Memory) which can read data from the arithmetic processor 90, and the like. The input circuit 92 is connected with various kinds of sensors and switches such as the rotation sensor 15, the magnetic sensor MS of each phase of each set, and the field current sensor 6, and is provided with A/D converter and the like for inputting output signals from the sensors and the switches to the arithmetic processor 90. The output circuit 93 is connected with electric loads such as a gate drive circuit which drive on and off of the switching devices of the first set and the second set of inverters IN1, IN2, and the converter 9, and is provided with a driving circuit and the like for outputting a control signal from the arithmetic processor 90. The communication circuit 94 communicates with the external apparatus.

Then, the arithmetic processor 90 runs software items (programs) stored in the storage apparatus 91 such as a ROM and collaborates with other hardware devices in the controller 10, such as the storage apparatus 91, the input circuit 92, and the output circuit 93, so that the respective functions of the control units 31 to 35 included in the controller 10 are realized. Various kinds of setting data items to be utilized in the control units 31 to 35 are stored, as part of software items (programs), in the storage apparatus 91 such as a ROM. Each function of the controller 10 will be explained in detail below.

### <Rotation Detection Unit 31>

The rotation detection unit 31 detects a magnetic pole position θ (a rotational angle θ of the rotor) and a rotational angle speed co of the rotor in an electrical angle. In the present embodiment, the rotation detection unit 31 detects the magnetic pole position θ (the rotational angle θ) and the rotational angle speed co in the electrical angle, based on the output signal of the rotation sensor 15. The magnetic pole position is set in the direction of the N pole of the electromagnet provided in the rotor. In the present embodiment, the magnetic pole position θ (the rotational angle θ) is a position (angle) of the magnetic pole (N pole) in the electrical angle based on the armature winding of U1 phase of first set. According to the phase difference π/6 between the armature windings of first set and the armature windings of second set shown in FIG. 2, the position (angle) of the magnetic pole (N pole) in the electrical angle based on the armature winding of U2 phase of second set becomes θ−π/6.

The rotation detection unit 31 may estimate the rotational angle (the magnetic pole position) without using the rotation sensor, based on current information which are obtained by superimposing a harmonic wave component on the current command value (so-called, sensorless system).

### <Armature Current Detection Unit 32>

The armature current detection unit 32 detects a armature winding current which flows into the armature winding of each phase of each set, based on the output signal of the magnetic sensor MS of each phase of each set. Specifically, the armature current detection unit 32 detects the armature winding current iu1s of U1 phase of first set, based on the output signal of the magnetic sensor MSu1 of U1 phase of first set; detects the armature winding current iv1s of V1 phase of first set, based on the output signal of the magnetic sensor MSv1 of V1 phase of first set; and detects the armature winding current iw1s of W1 phase of first set, based on the output signal of the magnetic sensor MSw1 of W1 phase of first set. The armature current detection unit 32 detects the armature winding current iu2s of U2 phase of second set, based on the output signal of the magnetic sensor MSu2 of U2 phase of second set; detects the armature winding current iv2s of V2 phase of second set, based on the output signal of the magnetic sensor MSv2 of V2 phase of second set; and detects the armature winding current iw2s of W2 phase of second set, based on the output signal of the magnetic sensor MSw2 of W2 phase of second set.

### <Armature Current Control Unit 33>

Using the vector control, such as the maximum torque/current control, the magnetic flux weakening control, and the Id=0 control, the armature current control unit 33 calculates first set of d-axis and q-axis current command values id1c, iq1c, and second set of d-axis and q-axis current command values id2c, iq2c, based on a torque command value, the rotational angle speed co, and the like.

The d-axis is defined in the direction of the magnetic pole (the N pole) of the magnet, and the q-axis is defined in the direction advanced to the d-axis by 90 degrees in the electrical angle.

As shown in a next equation, the armature current control unit 33 converts the current detection values iu1s, iv1s, iw1s of the three-phase armature windings of first set to d-axis current detection value id1s and q-axis current detection value iq1s of first set, by performing a three-phase/two-phase conversion and a rotating coordinate conversion based on the magnetic pole position θ.

$$( \begin{matrix}{i}_{d 1 s} \\ {i}_{q 1 s}\end{matrix} ) = \sqrt{\frac{2}{3}} ( \begin{matrix}sin ( θ + \frac{π}{2} ) & sin ( θ - \frac{π}{6} ) & sin ( θ - \frac{5}{6} π ) \\ - sin θ & - sin ( θ - \frac{2}{3} π ) & - sin ( θ + \frac{2}{3} π )\end{matrix} ) ( \begin{matrix}{i}_{u 1 s} \\ {i}_{v 1 s} \\ {i}_{w 1 s}\end{matrix} ) \qquad ( 1 )$$

As shown in a next equation, the armature current control unit 33 converts the current detection values iu2s, iv2s, iw2s of the three-phase armature windings of second set to d-axis current detection value id2s and q-axis current detection value iq2s of second set, by performing the three-phase/two-phase conversion and the rotating coordinate conversion based on the magnetic pole position θ.

$$( \begin{matrix}{i}_{d 2 s} \\ {i}_{q 2 s}\end{matrix} ) = \sqrt{\frac{2}{3}} ( \begin{matrix}- sin ( θ - \frac{2}{3} π ) & - sin ( θ + \frac{2}{3} π ) & - sin θ \\ - sin ( θ - \frac{π}{6} ) & - sin ( θ - \frac{5}{6} π ) & - sin ( θ + \frac{π}{2} )\end{matrix} ) ( \begin{matrix}{i}_{u 2 s} \\ {i}_{v 2 s} \\ {i}_{w 2 s}\end{matrix} ) \qquad ( 2 )$$

As mentioned above, since the magnetic pole position based on the armature winding of U2 phase of second set is becomes θ−π/6, the phase difference π/6 is provided between the coordinate conversion of the equation (1) and the coordinate conversion of the equation (2).

The armature current control unit 33 calculates d-axis and q-axis current command values Vd1c, Vq1c of first set by PI control or the like so that the d-axis and q-axis current detection values id1s, iq1s of first set approach the d-axis and q-axis current command values id1c, iq1c of first set. Then, as shown in a next equation, the armature current control unit 33 converts the d-axis and q-axis current command values Vd1c, Vq1c of first set to three-phase voltage command values Vu1c, Vv1c, Vw1c of first set, by performing a fixed coordinate conversion and a two-phase/three-phase conversion based on the magnetic pole position θ.

$$( \begin{matrix}{V}_{u 1 c} \\ {V}_{v 1 c} \\ {V}_{w 1 c}\end{matrix} ) = \sqrt{\frac{2}{3}} ( \begin{matrix}sin ( θ + \frac{π}{2} ) & - sin θ \\ sin ( θ - \frac{π}{6} ) & - sin ( θ - \frac{2}{3} π ) \\ sin ( θ - \frac{5}{6} π ) & - sin ( θ + \frac{2}{3} π )\end{matrix} ) ( \begin{matrix}{V}_{d 1 c} \\ {V}_{q 1 c}\end{matrix} ) \qquad ( 3 )$$

The armature current control unit 33 calculates d-axis and q-axis current command values Vd2c, Vq2c of second set by PI control or the like so that the d-axis and q-axis current detection values id2s, iq2s of second set approach the d-axis and q-axis current command values id2c, iq2c of second set. Then, as shown in a next equation, the armature current control unit 33 converts the d-axis and q-axis current command values Vd2c, Vq2c of second set to three-phase voltage command values Vu2c, Vv2c, Vw2c of second set, by performing the fixed coordinate conversion and the two-phase/three-phase conversion based on the magnetic pole position θ.

$$( \begin{matrix}{V}_{u 2 c} \\ {V}_{v 2 c} \\ {V}_{w 2 c}\end{matrix} ) = \sqrt{\frac{2}{3}} ( \begin{matrix}- sin ( θ - \frac{2}{3} π ) & - sin ( θ - \frac{π}{6} ) \\ - sin ( θ + \frac{2}{3} π ) & - sin ( θ - \frac{5}{6} π ) \\ - sin θ & - sin ( θ + \frac{π}{2} )\end{matrix} ) ( \begin{matrix}{V}_{d 2 c} \\ {V}_{q 2 c}\end{matrix} ) \qquad ( 4 )$$

As similar to the equation (1) and the equation (2), the phase difference π/6 are provided between the coordinate conversion of the equation (3) and the coordinate conversion of the equation (4). The armature current control unit 33 may add well-known modulation, such as the space vector modulation or the two-phase modulation, to the three-phase voltage command values of first set and second set, in order to improve the voltage utilization factor.

The armature current control unit 33 controls on/off the plural switching devices of the first set of inverter IN1 by PWM control (Pulse Width Modulation), based on the three-phase voltage command values Vu1c, Vv1c, Vw1c of first set. The armature current control unit 33 controls on/off the plural switching devices of the second set of inverter IN2 by PWM control, based on the three-phase voltage command values Vu2c, Vv2c, Vw2c of second set. As PWM control, well-known the carrier wave comparison PWM or the space vector PWM is used.

### <Control of Field Current>

The field current detection unit 34 detects a field current ifs which is current flowing into the field winding 4, based on the output signal of the field current sensor 6. The field current control unit 35 sets a field current command value ifc, based on the torque command value and the like. The field current control unit 35 calculates the field voltage command value Vf by PI control or the like so that the detection value ifs of field current approaches the field current command value ifc. Then, the field current control unit 35 controls on/off the plural switching devices of the converter 9 by PWM control, based on the field voltage command value Vf.

### 1-7. Arrangement of Magnetic Sensors MS for Reducing Current Detection Error Due to Magnetic Flux of Rotor

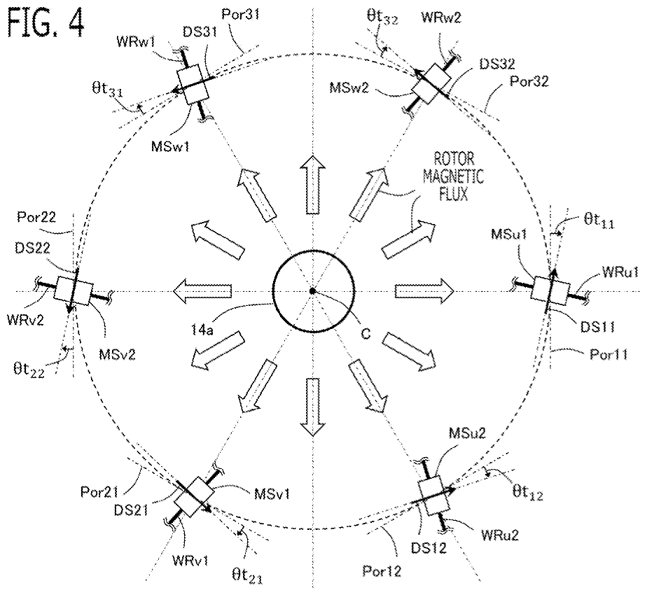

FIG. 4 is a schematic diagram which shows the arrangement position of the magnetic sensor MS of each phase of each set when viewing in the axial direction. The magnetic sensor MS of each phase of each set is disposed at a position where a magnetic flux radially emitted from the rotor 14 in the radial direction crosses.

In the present embodiment, the magnetic flux direction and the flux density of the rotor which cross each magnetic sensor MS does not change according to rotation of the rotor. In other words, the flux density radially emitted from a part (in this example, the rotation axis 14a) of the rotor disposed on the radial-direction inner side of each magnetic sensor MS does not change in the circumferential direction. The magnetic flux direction and the flux density of the rotor which cross each magnetic sensor MS may change to some degree (for example, within a range of ±10%) according to rotation of the rotor, due to the influence of the magnetic flux emitted from the magnetic poles of the N pole and the S pole which are disposed alternately in the circumferential direction.

### <Lundell Type Rotor>

In the present embodiment, the rotor 14 is a Lundell type (it is also called as a claw pole type) rotor. The rotation axis 14a of the rotor 14 is disposed on the radial-direction inner side of the magnetic sensor MS of each phase of each set. The part of the rotation axis 14a disposed on the radial-direction inner side of each magnetic sensor MS becomes the N pole or the S pole. Then, the magnetic flux radially emitted to the radial direction from the rotation axis 14a crosses each magnetic sensor MS.

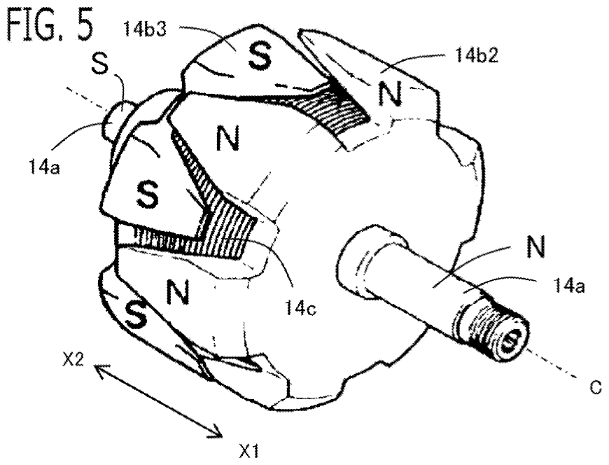

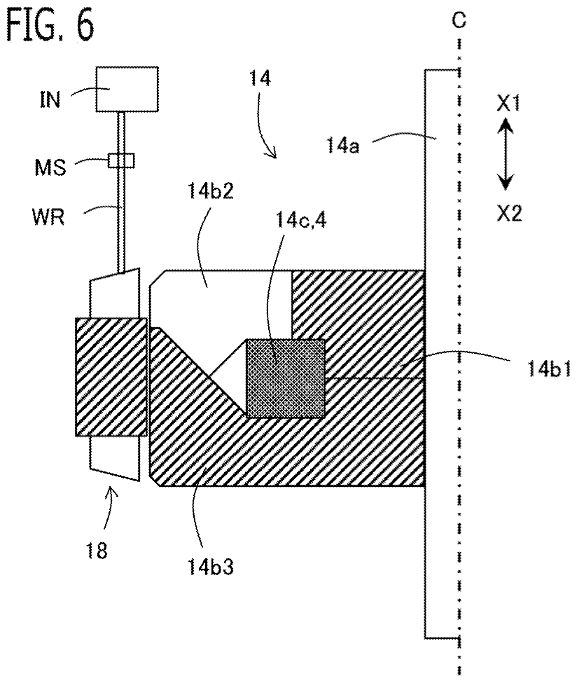

FIG. 5 shows the perspective view of the Lundell type rotor, and FIG. 6 shows the cross-sectional view of the AC rotary machine. The rotor 14 has the rotation axis 14a which is cylindrical columnar or the cylindrical tubular, a field core 14b integrally rotated with the rotation axis 14a, and a field winding 14c wound around the field core 14b. The field core 14b is provided with a cylindrical tubular central part 14b1 which fitted to the outer circumferential face of the rotation axis 14a; plural first claw parts 14b2 which extended to the radial-direction outside from the axial direction one side X1 end of the central part 14b1, and then extended to the axial direction the other side X2 on the radial-direction outside of the central part 14b1; and plural second claw parts 14b3 which extended to the radial-direction outside from the axial direction the other side X2 end of the central part 14b1, and then extended to the axial direction one side X1 on the radial-direction outside of the central part 14b1. The first claw parts 14b2 and the second claw parts 14b3 are disposed alternately in the circumferential direction, and become different magnetic poles mutually. For example, six or eight the first claw parts 14b2 and the second claw parts 14b3 are provided, respectively. The number of pole pairs is 6 or 8.

The field winding 14c is wound concentrically centering on the axial center C, in the peripheral part of the rotation axis 14a and the central part 14b1 of the field core. The magnetic flux in the axial direction is generated on the radial-direction inner side of the field winding 14c, and the axial direction one side X1 part of the rotor and the axial direction the other side X2 part become different magnetic poles mutually. In order to assist the field winding 14c, a permanent magnet may be provided in the peripheral part of the rotation axis 14a and the central part 14b1 of the field core. In order to decrease leakage of the magnetic flux between magnetic poles, a permanent magnet magnetized in the circumferential direction may be disposed between the first claw part 14b2 and the second claw part 14b3.

Accordingly, in the Lundell type rotor in which the field winding 14c is wound concentrically centering on the axial center C, the axial direction one side X1 part of the rotor and the axial direction one side X1 part of the rotor become different magnetic poles mutually. In the following, the case where the axial direction one side X1 part of the rotor is the N pole, and the axial direction the other side X2 part of the rotor is the S pole will be explained. The N pole and the S pole may be exchanged, and the axial direction one side X1 and the axial direction the other side X2 may be exchanged.

The part of the rotation axis 14a projected from the field core 14b to the axial direction one side X1, and the axial direction one side X1 part of the field core 14b including the first claw parts 14b2 become the N pole. The part of the rotation axis 14a projected from the field core 14b to the axial direction the other side X2, and the axial direction the other side X2 part of the field core 14b including the second claw parts 14b3 become the S pole.

### <Arrangement of Each Magnetic Sensor>

The magnetic sensor MS of each phase of each set is disposed on the axial direction one side X1 of the rotor, and the magnetic flux radially emitted in the radial direction from the axial direction one side X1 part of the rotor crosses the magnetic sensor of each phase of each set. The magnetic flux which crosses the magnetic sensor MS may also include the component of the axial direction in addition to the component of the radial direction.

As shown in FIG. 6, the first set and the second set of inverters IN1, IN2 are disposed on the axial direction one side X1 of the stator 18. The connection line WR of each phase of each set extends from the first set and the second set of armature windings to the axial direction one side X1, and is connected to the first set and the second set of inverters IN1, IN2. The connection line WR of each phase of each set is disposed on the radial-direction outside of the axial direction one side X1 part of the rotation axis 14a. And, the magnetic sensor MS of each phase of each set which is disposed opposite to the connection line WR of each phase of each set is disposed on the radial-direction outside of the axial direction one side X1 part of the rotation axis 14a.

The magnetic flux radially emitted in the radial direction from the axial direction one side X1 part of the rotation axis 14a crosses the magnetic sensor MS of each phase of each set. The magnetic flux radially emitted in the radial direction from the axial direction one side X1 end of the field core 14b may cross the magnetic sensor MS of each phase of each set.

In the present embodiment, as shown in FIG. 4, the magnetic sensors MS of first set and the magnetic sensors MS of second set are alternately disposed at equal angle intervals in the circumferential direction. The magnetic sensors MS is disposed at equal angle intervals of π/3 (60 degrees) of the mechanical angle in the circumferential direction in order of MSu1, MSu2, MSv1, MSv2, MSw1, and MSw2 on the same circle centering on the axial center C. The order of the magnetic sensors MS in the circumferential direction may be any order. The magnetic sensors MS may not be disposed at equal angle intervals in the circumferential direction. By disposing the magnetic sensors MS at equal angle intervals in the circumferential direction, a detection error of the magnetic sensor MS due to the magnetic flux which is generated by current of other connection lines WR to which the magnetic sensor MS is not disposed opposite can be reduced. If a part of each magnetic sensor MS is on the same circle, it can be interpreted as disposing on the same circle.

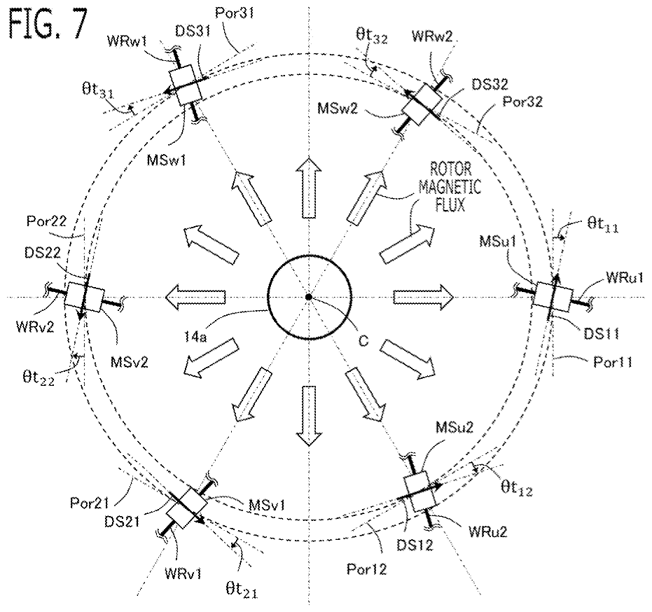

As shown in FIG. 7, a radius of the same circle on which the magnetic sensors MSu1, MSv1, MSw1 of three-phase of first set are disposed may be different from a radius of the same circle on which the magnetic sensors MSu2, MSv2, MSw2 of three-phase of second set are disposed. Even in this case, as described later, in each set, the current detection error due to the magnetic flux of the rotor can be reduced.

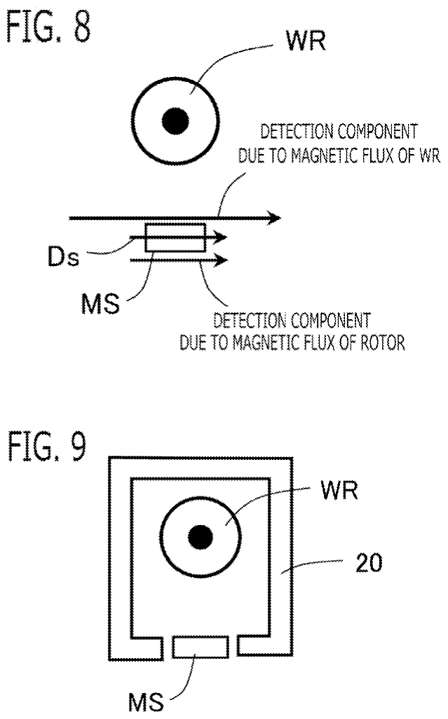

Each magnetic sensor MS (sensor element) detects a flux density component of a magnetic flux detecting direction DS of a magnetic flux which crosses the sensor element, and outputs the signal according to the detected flux density. The magnetic flux detecting direction DS becomes a specific direction according to an arrangement direction of the sensor element. As FIG. 8 shows a schematic diagram viewed in the extending direction of the connection line WR, the magnetic flux detecting direction DS of each magnetic sensor MS (sensor element) is disposed so as to be parallel to a direction of the magnetic flux which is generated by the current which flows through each connection line WR. That is to say, the magnetic flux detecting direction DS of each magnetic sensor MS is disposed so as to be parallel to the circumferential direction centering on each connection line WR. As shown in FIG. 9, the magnetic-flux collecting core 20 may be provided in each magnetic sensor MS.

In the example of FIG. 4, the part of each connection line WR to which each magnetic sensor MS is disposed opposite extends to the radial direction substantially. Each magnetic sensor MS (sensor element) is disposed opposite to the connection line WR, on the axial direction the other side X2 of the part of the connection line WR which extends to the radial direction.

Each magnetic sensor MS detects the flux density which is generated in proportion to the current of the opposing connection line WR. If the magnetic flux detecting direction DS of the magnetic sensor MS is orthogonal to the magnetic flux of the rotor of the radial direction which crosses the sensor element, a flux density component of the magnetic flux detecting direction DS of the magnetic flux of the rotor is not generated. Accordingly, the detection error of the current due to the magnetic flux of the rotor does not occur. However, if the magnetic flux detecting direction DS of the magnetic sensor MS is not orthogonal to the magnetic flux of the rotor of the radial direction which crosses the sensor element, and inclines to a radial orthogonal plane Por which is a plane orthogonal to the radial direction which passes the sensor element, a flux density component of the magnetic flux detecting direction DS of the magnetic flux of the rotor is generated according to an inclination angle θt. Accordingly, the detection error of the current due to the magnetic flux of the rotor occurs.

Herein, θt11 is defined as an inclination angle of the magnetic flux detecting direction DS11 of the magnetic sensor MSu1 with respect to the radial orthogonal plane Por11 which is a plane orthogonal to the radial direction which passes the center of the magnetic sensor MSu1 of U1 phase of first set. θt21 is defined as an inclination angle of the magnetic flux detecting direction DS21 of the magnetic sensor MSv1 with respect to the radial orthogonal plane Por21 which is a plane orthogonal to the radial direction which passes the center of the magnetic sensor MSv1 of V1 phase of first set. θt31 is defined as an inclination angle of the magnetic flux detecting direction DS31 of the magnetic sensor MSw1 with respect to the radial orthogonal plane Por31 which is a plane orthogonal to the radial direction which passes the center of the magnetic sensor MSw1 of W1 phase of first set. θt12 is defined as an inclination angle of the magnetic flux detecting direction DS12 of the magnetic sensor MSu2 with respect to the radial orthogonal plane Por12 which is a plane orthogonal to the radial direction which passes the center of the magnetic sensor MSu2 of U2 phase of second set. θt22 is defined as an inclination angle of the magnetic flux detecting direction DS22 of the magnetic sensor MSv2 with respect to the radial orthogonal plane Por22 which is a plane orthogonal to the radial direction which passes the center of the magnetic sensor MSv2 of V2 phase of second set. θt32 is defined as an inclination angle of the magnetic flux detecting direction DS32 of the magnetic sensor MSw2 with respect to the radial orthogonal plane Por32 which is a plane orthogonal to the radial direction which passes the center of the magnetic sensor MSw2 of W2 phase of second set. In the present embodiment, the magnetic flux detecting direction DS of each magnetic sensor MS is orthogonal to the axial direction. The inclination angle θt of each magnetic sensor becomes an inclination angle with respect to a tangential direction of a circle which passes each magnetic sensor MS and centers on the axial center C. Herein, the case where the direction of current which flows through the connection line WR is the radial-direction outside about all phases is explained. However, about partial phases or all phases, the direction of current may be the radial-direction inner side. In this case, a similar concept can be made, if the magnetic flux detecting direction DS is set to the opposite direction and the inclination angle θt is set in accordance with it.

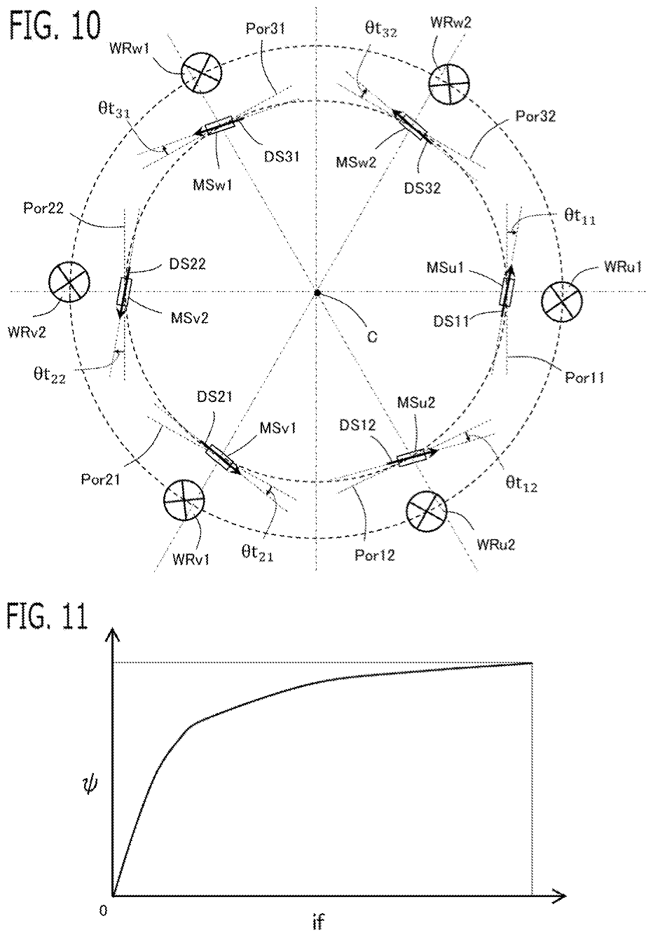

As shown in FIG. 10, the part of each connection line WR to which each magnetic sensor MS is disposed opposite may extend to the axial direction. Then, the magnetic sensor MS (sensor element) may be disposed opposite to the connection line WR on the radial-direction inner side (or radial-direction outside) of the part of the connection line WR which extends to the axial direction. Even in this case, if the magnetic flux detecting direction DS of the magnetic sensor MS inclines to the radial orthogonal plane Por which is a plane orthogonal to the radial direction which passes the sensor element, the flux density component of the magnetic flux detecting direction DS of the magnetic flux of the rotor is generated according to the inclination angle θt. Accordingly, the detection error of the current due to the magnetic flux of the rotor occurs.

### <Influence Due to Current Detection Error>

If the current detection error due to the magnetic flux of the rotor is considered, the current detection values iu1s to iw2s of each phase of each set detected by the magnetic sensor MS of each phase of each set is represented by a next equation.

$$\{ \begin{matrix}{i}_{u 1 s} = {i}_{u 1} + {δ}_{u 1} = \sqrt{2} I cos ( θ + β ) + {δ}_{u 1} \\ {i}_{v 1 s} = {i}_{v 1} + {δ}_{v 1} = \sqrt{2} I cos ( θ + β - \frac{2}{3} π ) + {δ}_{v 1} \\ {i}_{w 1 s} = {i}_{w 1} + {δ}_{w 1} = \sqrt{2} I cos ( θ + β + \frac{2}{3} π ) + {δ}_{w 1} \\ {i}_{u 2 s} = {i}_{u 2} + {δ}_{u 2} = \sqrt{2} I cos ( θ + β - \frac{π}{6} ) + {δ}_{u 2} \\ {i}_{v 2 s} = {i}_{v 2} + {δ}_{v 2} = \sqrt{2} I cos ( θ + β - \frac{5}{6} π ) + {δ}_{v 2} \\ {i}_{w 2 s} = {i}_{w 2} + {δ}_{w 2} = \sqrt{2} I cos ( θ + β + \frac{π}{2} ) + {δ}_{w 2}\end{matrix} \qquad ( 5 )$$

Herein, iu1 is a true current value which flows through the armature winding of U1 phase of first set; θu1 is a detection error component of the current of U1 phase of first set due to the magnetic flux of the rotor; iv1 is a true current value which flows through the armature winding of V1 phase of first set; δv1 is a detection error component of the current of V1 phase of first set due to the magnetic flux of the rotor; iw1 is a true current value which flows through the armature winding of W1 phase of first set; and Owl is a detection error component of the current of V1 phase of first set due to the magnetic flux of the rotor. iu2 is a true current value which flows through the armature winding of U2 phase of second set; δu2 is a detection error component of the current of U2 phase of second set due to the magnetic flux of the rotor; iv2 is a true current value which flows through the armature winding of V2 phase of second set; δv2 is a detection error component of the current of V2 phase of second set due to the magnetic flux of the rotor; iw2 is a true current value which flows through the armature winding of W2 phase of second set; and δw2 is a detection error component of the current of W2 phase of second set due to the magnetic flux of the rotor. I is a magnitude of the current vector of each set, and β is a phase of the current vector to the q-axis of each set. Due to the phase difference π/6 between the armature windings of first set and the armature windings of second set shown in FIG. 2, the true current values of three-phase of second set is delayed by the phase difference π/6 with respect to the true current values of three-phase of first set.

<Detection Errors of d-Axis and q-Axis Due to Magnetic Flux of Rotor>

The equation (6) shows a d-axis current detection value Id1s of first set and a q-axis current detection value Iq1s of first set which are obtained by substituting the first equation to the third equation of the equation (5) for the equation (1), and performing a coordinate conversion. The equation (7) shows a d-axis current detection value Id2s of second set and a q-axis current detection value Iq2s of second set which are obtained by substituting the fourth equation to the sixth equation of the equation (5) for the equation (2), and performing a coordinate conversion.

$$\begin{matrix}\{ \begin{matrix}\begin{matrix}{i}_{d 1 s} = \sqrt{3} I sin ( β + \frac{π}{2} ) + \\ \sqrt{\frac{2}{3}} \{ {δ}_{u 1} sin ( θ + \frac{π}{2} ) + {δ}_{v 1} sin ( θ - \frac{π}{6} ) + {δ}_{w 1} sin ( θ - \frac{5}{6} π ) \}\end{matrix} \\ \begin{matrix}{i}_{q 1 s} = \sqrt{3} I sin β + \\ \sqrt{\frac{2}{3}} \{ - {δ}_{u 1} sin θ - {δ}_{v 1} sin ( θ - \frac{2}{3} π ) - {δ}_{w 1} sin ( θ + \frac{2}{3} π ) \}\end{matrix}\end{matrix} & ( 6 ) \\ \{ \begin{matrix}\begin{matrix}{i}_{d 2 s} = \sqrt{3} I sin ( β + \frac{π}{2} ) + \\ \sqrt{\frac{2}{3}} \{ - {δ}_{u 2} sin ( θ - \frac{2}{3} π ) - {δ}_{v 2} sin ( θ + \frac{2}{3} π ) - {δ}_{w 2} sin θ \} \end{matrix} \\ \begin{matrix}{i}_{q 2 s} = \sqrt{3} I sin β + \\ \sqrt{\frac{2}{3}} \{ - {δ}_{u 2} sin ( θ - \frac{π}{6} ) - {δ}_{v 2} ( θ - \frac{5}{3} π ) - {δ}_{w 2} sin ( θ + \frac{π}{2} ) \}\end{matrix}\end{matrix} & ( 7 )\end{matrix}$$

Herein, the first term of the right side of each of the equation (6) and the equation (7) corresponds to the d-axis or q-axis true current. Accordingly, the second term of the right side of each of the equation (6) and the equation (7) is a detection error component of d-axis or q-axis current due to the magnetic flux of the rotor.

An output torque T of the AC rotary machine can be represented by a next equation. Pm is the number of pole pairs, ψ is the interlinkage flux of the magnet, Ld is the d-axis inductance, and Lq is the q-axis inductance. As shown in the equation (8), the output torque T changes according to the d-axis and q-axis true currents id, iq of each set.

T=Pₘ{(i_{q1}+i_{q2})φ+(L_{d}−L_{q})(i_{d1}i_{q1}+i_{d2}i_{q2})} (8)

If the current feedback control is performed based on the d-axis and q-axis current detection values ids, iqs including the error due to the magnetic flux of the rotor, the d-axis and q-axis true current values id, iq are deviated from the d-axis and q-axis current command values idc, iqc by error. As shown in the equation (8), since the output torque T changes according to the d-axis and q-axis true currents id, iq, the actual output torque is deviated from the target output torque which corresponds to the d-axis and q-axis current command values idc, iqc, according to the detection error component included in the d-axis and q-axis current detection values ids, iqs. Since the second term of the right side of each of the equation (6) and the equation (7) is a vibration component which vibrates according to the magnetic pole position θ, a torque ripple is generated according to the detection error in the output torque T.

The three terms of sin( ) in the detection error component of the second term of the right side of each of the equation (6) and the equation (7) are different in phase by 2π/3 (120 degrees) with each other. Accordingly, as shown in the equation (9), in each set, by setting the detection error component δ of each phase which is a coefficient of each sin( ) to the same value with each other, the three terms of sin( ) are canceled with each other, and a total value can be set to 0. Therefore, as shown in the equation (10), in the d-axis and q-axis current detection values ids, iqs of each set, the detection error component δ of each phase due to the magnetic flux of the rotor can be canceled with each other, and it can be reduced to 0. And, the d-axis and q-axis current detection values ids, iqs of each set can be brought close to the d-axis and q-axis true currents id, iq of each set.

$$\begin{matrix}\{ \begin{matrix}{δ}_{u 1} = {δ}_{v 1} = {δ}_{w 1} \\ {δ}_{u 2} = {δ}_{v 2} = {δ}_{w 2}\end{matrix} & ( 9 ) \\ \{ \begin{matrix}{i}_{d 1 s} ≅ \sqrt{3} I sin ( β + \frac{π}{2} ) = {i}_{d 1} \\ {i}_{q 1 s} ≅ \sqrt{3} I sin β = {i}_{q 1} \\ {i}_{d 2 s} ≅ \sqrt{3} I sin ( β + \frac{π}{2} ) = {i}_{d 2} \\ {i}_{q 2 s} ≅ \sqrt{3} I sin β = {i}_{q 2}\end{matrix} & ( 10 )\end{matrix}$$

Then, by performing current feedback control based on the d-axis and q-axis current detection values ids, iqs in which the detection error components of each phase due to the magnetic flux of the rotor are canceled, the d-axis and q-axis true current values id, iq can be brought close to the d-axis and q-axis current command values idc, iqc. Accordingly, the actual output torque can be controlled to the target output torque which corresponds to the d-axis and q-axis current command values idc, iqc with good accuracy.

The detection error component δ of the current of each phase of each set due to the magnetic flux of the rotor is represented by a next equation, using the inclination angle θt of the magnetic flux detecting direction DS of the magnetic sensor of each phase of each set with respect to the radial orthogonal plane Por which is a plane orthogonal to the radial direction which passes each magnetic sensor MS.

$$\{ \begin{matrix}{δ}_{u 1} = {K}_{bi} {B}_{r 1} sin θ {t}_{11} = {K}_{bi} {B}_{s 11} \\ {δ}_{v 1} = {K}_{bi} {B}_{r 1} sin θ {t}_{21} = {K}_{bi} {B}_{s 21} \\ {δ}_{w 1} = {K}_{bi} {B}_{r 1} sin θ {t}_{31} = {K}_{bi} {B}_{s 31} \\ {δ}_{u 2} = {K}_{bi} {B}_{r 2} sin θ {t}_{12} = {K}_{bi} {B}_{s 12} \\ {δ}_{v 2} = {K}_{bi} {B}_{r 2} sin θ {t}_{22} = {K}_{bi} {B}_{s 22} \\ {δ}_{w 2} = {K}_{bi} {B}_{r 2} sin θ {t}_{32} = {K}_{bi} {B}_{s 32}\end{matrix} \qquad ( 11 )$$

Herein, Br1 is the flux density of the magnetic flux of the rotor in the radial direction which passes each magnetic sensor of first set. In the present embodiment, since each magnetic sensor of first set is disposed on the same circle centering on the axial center C, Br1 is the same value for each magnetic sensor of first set. Br2 is the flux density of the magnetic flux of the rotor in the radial direction which passes each magnetic sensor of second set. In the present embodiment, since each magnetic sensor of second set is disposed on the same circle centering on the axial center C, Br2 is the same value for each magnetic sensor of second set. In the present embodiment, since all the magnetic sensors of first set and second set are disposed on the same circle, it is Br1=Br2.

By Br×sin θt, the detection component Bs of the rotor flux density which is the flux density component of the rotor detected by each magnetic sensor is calculated. Kbi is a conversion coefficient for converting from the detection component Bs of the rotor flux density into the current detection value. The inclination angle θtk1 (k is an integer greater than or equal to 1) is the inclination angle of the k-th phase of first set; and the first phase, the second phase, and the third phase are used instead of U1 phase, V1 phase, and W1 phase. The inclination angle θth2 (h is an integer greater than or equal to 1) is the inclination angle of the h-th phase of second set; and the first phase, the second phase, and the third phase are used instead of U2 phase, V2 phase, and W2 phase. Similarly, Bsk1 is the detection component of the k-th phase of first set, and Bsh2 is the detection component of the h-th phase of second set.

In order to establish the equation (9), as shown in a next equation, in each set, the magnetic sensors of three-phase may be disposed so that the detection components Bs of the rotor flux density become equal with each other.

$$\{ \begin{matrix}{B}_{s 11} = {B}_{s 21} = {B}_{s 31} \\ {B}_{s 12} = {B}_{s 22} = {B}_{s 32}\end{matrix} \qquad ( 12 )$$

Then, in order to establish the equation (12), as shown in a next equation, in each set, a sine value of the inclination angle θt of the magnetic flux detecting direction DS of the magnetic sensor of each phase with respect to the radial orthogonal plane Por which is a plane orthogonal to the radial direction which passes each magnetic sensor may be equal with each other.

$$\{ \begin{matrix}sin θ {t}_{11} = sin θ {t}_{21} = sin θ {t}_{31} \\ sin θ {t}_{12} = sin θ {t}_{22} = sin θ {t}_{32}\end{matrix} \qquad ( 13 )$$

According to this configuration, as mentioned above, in the d-axis and q-axis current detection values ids, iqs of each set, the detection error component δ of each phase due to the magnetic flux of the rotor can be canceled with each other, and it can be reduced to 0. And, the d-axis and q-axis current detection values ids, iqs of each set can be brought close to the d-axis and q-axis true currents id, iq of each set. Accordingly, the control accuracy of output torque can be improved.

If the inclination angle θt of each magnetic sensor is set to π/2 (90 degrees), the direction of the magnetic flux of the rotor coincides with the magnetic flux detecting direction DS of the magnetic sensor. Accordingly, the detection component Bs of the rotor flux density and the detection error component δ which are expressed by the equation (11) become the maximum value. As shown in the equation (5), the center value of the current detection value is offset by the detection error component δ. Accordingly, if the offset becomes large, in order to be able to detect an entire range, it is necessary to lower the resolution of A/D conversion. Therefore, in order to make the absolute value of the detection error component δ small to some degree, for example, as shown in a next equation, each magnetic sensor MS may be disposed so that the absolute value of the sine value of the inclination angle θt become less than 1/√2. 1/√2 corresponds to θt=±45 degrees.

$$\{ \begin{matrix}\vert sin θ {t}_{11} \vert < \frac{1}{\sqrt{2}} \\ \vert sin θ {t}_{21} \vert < \frac{1}{\sqrt{2}} \\ \vert sin θ {t}_{31} \vert < \frac{1}{\sqrt{2}} \\ \vert sin θ {t}_{12} \vert < \frac{1}{\sqrt{2}} \\ \vert sin θ {t}_{22} \vert < \frac{1}{\sqrt{2}} \\ \vert sin θ {t}_{32} \vert < \frac{1}{\sqrt{2}}\end{matrix} \qquad ( 14 )$$

If a position displacement in the radial direction occurs when attaching the magnetic sensor MS, as shown in a next equation, a variation ΔBr occurs in the flux density Br of the rotor in the radial direction which passes the magnetic sensor MS, and an error occurs in the detection error component δ. However, the fluctuation ΔBr with respect to the flux density Br is small, and the influence due to the position displacement can be suppressed by making the absolute value of the sine value of the inclination angle θt small.

δᵤ₁=K_{bi}(Bᵣ₁+ΔBr)sin θt₁₁ (15)

Therefore, for example, as shown in a next equation, if each magnetic sensor MS is disposed so that the absolute value of the sine value of the inclination angle θt becomes less than 1/5, the influence of the attachment error of the magnetic sensor MS can be reduced more, and it is more preferred. 1/5 corresponds to θt≈±11.3 degrees.

$$\{ \begin{matrix}\vert sin θ {t}_{11} \vert < \frac{1}{5} \\ \vert sin θ {t}_{21} \vert < \frac{1}{5} \\ \vert sin θ {t}_{31} \vert < \frac{1}{5} \\ \vert sin θ {t}_{12} \vert < \frac{1}{5} \\ \vert sin θ {t}_{22} \vert < \frac{1}{5} \\ \vert sin θ {t}_{32} \vert < \frac{1}{5}\end{matrix} \qquad ( 16 )$$

In each set, although the magnetic sensors MS of three-phase may be disposed on the same circle, if a part of each magnetic sensor MS is on the same circle, the variation ΔBr of the flux density due to the attachment error is minute. Accordingly, the detection error of the d-axis and q-axis currents caused by the attachment error is allowable. Although the case where the magnetic sensor MS of each phase of each set is disposed on the same circle was explained, the detection error component δ of the current of each phase of each set due to the magnetic flux of the rotor can be expressed using Br×sin θt like the equation (11). Accordingly, by making θt small on the radial-direction inner side where the magnetic flux is large, making θt large on the radial-direction outside where the magnetic flux is small, and making Br×sin θt equal, the detection error component δ of the current of each phase of each set due to the magnetic flux of the rotor can be made equal.

### 2. Embodiment 2

The current detection apparatus according to Embodiment 2 is explained with reference to drawings. Similar to Embodiment 1, the current detection apparatus is built into the AC rotary machine 1 and the controller 10. The explanation for constituent parts the same as those in Embodiment 1 will be omitted. The basic configuration of the AC rotary machine 1 and the controller 10 according to the present embodiment is the same as that of Embodiment 1. It is different from Embodiment 1 in that the current detection value of each phase of each set is corrected by a detection error correction value according to the field current if.

### <Variation of Current Detection Error δ According to Field Current If>

As shown in FIG. 11, according to the field current if, the magnetic flux ψ of the rotor changes, and the flux density of the rotor in the radial direction which passes each magnetic sensor MS changes. Accordingly, according to the field current if, the current detection error δ which is caused by the magnetic flux of the rotor changes.

In the present embodiment, the armature current detection unit 32 calculates a current error value Δiδ of each phase of each set, based on the detection value ifs of the field current, corrects the current detection value is of each phase of each set by the current error value Δiδ of each phase of each set, and calculates a current detection value iscr of each phase of each set after correction.

$$\{ \begin{matrix}{i}_{u 1 scr} = {i}_{u 1 s} - Δ {i}_{δ u 1} , & Δ {i}_{δ u 1} = {f}_{δ u 1} ( {i}_{fs} ) \\ {i}_{v 1 scr} = {i}_{v 1 s} - Δ {i}_{δ v 1} , & Δ {i}_{δ v 1} = {f}_{δ v 1} ( {i}_{fs} ) \\ {i}_{w 1 scr} = {i}_{w 1 s} - Δ {i}_{δ w 1} , & Δ {i}_{δ w 1} = {f}_{δ w 1} ( {i}_{fs} ) \\ {i}_{u 2 scr} = {i}_{u 2 s} - Δ {i}_{δ u 2} , & Δ {i}_{δ u 2} = {f}_{δ u 2} ( {i}_{fs} ) \\ {i}_{v 2 scr} = {i}_{v 2 s} - Δ {i}_{δ v 2} , & Δ {i}_{δ v 2} = {f}_{δ v 2} ( {i}_{fs} ) \\ {i}_{w 2 scr} = {i}_{w 2 s} - Δ {i}_{δ w 2} , & Δ {i}_{δ w 2} = {f}_{δ w 2} ( {i}_{fs} )\end{matrix} \qquad ( 17 )$$

Herein, fδ( ) of each phase of each set is an error calculation function in which a relationship between the detection value ifs of the field current and the current error value Δiδ of each phase of each set is preliminarily set, and it is stored in the storage apparatus 91. The error calculation function fδ( ) of each phase of each set is a map data, a polynomial, or the like. By referring the error calculation function fδ( ) of each phase of each set, the armature current detection unit 32 calculates the current error value Δiδ of each phase of each set corresponding to the present detection value ifs of the field current. The current detection error δ of each phase of each set is measured or calculated in each operating point of the field current if by experiment or analysis, and the error calculation function fδ( ) of each phase of each set is preliminarily set using the current detection error δ of each phase of each set in each operating point of the field current if.

As shown in FIG. 11, in the region where the field current if is small, the magnetic flux ψ of the rotor changes linearity with respect to the change of the field current if. On the other hand, in the region where the field current if is large, the magnetic flux ψ of the rotor changes nonlinear with respect to the change of the field current if. In many AC rotary machines, it is designed to mainly operate in the linear region. Accordingly, in order to simplify processing, the armature current detection unit 32 may calculate the current error value Δiδ of each phase of each set by multiplying a preliminarily set error calculation coefficient Kδ of each phase of each set to the detection value ifs of the field current.

$$\{ \begin{matrix}{i}_{u 1 scr} = {i}_{u 1 s} - Δ {i}_{δ u 1} , & Δ {i}_{δ u 1} = {K}_{δ u 1} {i}_{fs} \\ {i}_{v 1 scr} = {i}_{v 1 s} - Δ {i}_{δ v 1} , & Δ {i}_{δ v 1} = {K}_{δ v 1} {i}_{fs} \\ {i}_{w 1 scr} = {i}_{w 1 s} - Δ {i}_{δ w 1} , & Δ {i}_{δ w 1} = {K}_{δ w 1} {i}_{fs} \\ {i}_{u 2 scr} = {i}_{u 2 s} - Δ {i}_{δ u 2} , & Δ {i}_{δ u 2} = {K}_{δ u 2} {i}_{fs} \\ {i}_{v 2 scr} = {i}_{v 2 s} - Δ {i}_{δ v 2} , & Δ {i}_{δ v 2} = {K}_{δ v 2} {i}_{fs} \\ {i}_{w 2 scr} = {i}_{w 2 s} - Δ {i}_{δ w 2} , & Δ {i}_{δ w 2} = {K}_{δ w 2} {i}_{fs}\end{matrix} \qquad ( 18 )$$

The error calculation coefficient Kδ of each phase of each set is preliminarily set using the current detection error δ of each phase of each set which is measured by experiment or calculated by analysis in each operating point of the field current if, and it is stored in the storage apparatus 91.

Then, the armature current control unit 33 calculates the d-axis and q-axis current detection values ids, iqs of each set, by performing the coordinate conversion of the equation (1) and the equation (2) to the current detection values iscr of three-phase after correction of each set, and performs current control.

### <Abnormality Determination>

As shown in a next equation, if the correction of the current error by the rotor magnetic flux is performed, in each set, a total of the current detection values of three-phase after correction theoretically becomes 0.

$$\{ \begin{matrix}{i}_{u 1 scr} = {i}_{v 1 scr} + {i}_{w 1 scr} = 0 \\ {i}_{u 2 scr} = {i}_{v 2 scr} + {i}_{w 2 scr} = 0\end{matrix} \qquad ( 19 )$$

Then, as shown in a next equation, in each set, the armature current detection unit 32 determines that abnormality occurred, when the total of the current detection values of three-phase after correction exceeds a preliminarily set determination range.

$$\{ \begin{matrix}{i}_{sum\_min} \leq {i}_{u 1 scr} + {i}_{v 1 scr} + {i}_{w 1 scr} \leq {i}_{sum\_max} \\ {i}_{sum\_min} \leq {i}_{u 2 scr} + {i}_{v 2 scr} + {i}_{w 2 scr} \leq {i}_{sum\_max}\end{matrix} \qquad ( 20 )$$

The armature current detection unit 32 determines that it is normal when the equation (20) is established, and determines that it is abnormal when the equation (20) is not established. Herein, a determination lower limit value isum_min and a determination upper limit value isum_max are preliminarily set considering the variation width due to variation factors, such as the temperature characteristic of the magnetic sensor, and the aging change.

<Abnormality Determination Using Current Detection Value without Correction>

Herein, the abnormality may be determined based on the current detection value to which correction is not performed. For example, as shown in a next equation, in each set, the armature current detection unit 32 may calculate a total error value Δiδsum, based on the detection value ifs of the field current, and may determine that abnormality occurred when a value obtained by subtracting the total error value Δiδsum from a total value of the current detection values of three-phase exceeds the preliminarily set determination range.

$$\{ \begin{matrix}{i}_{sum\_min} \leq {i}_{u 1 s} + {i}_{v 1 s} + {i}_{w 1 s} - Δ {i}_{δ sum 1} \leq {i}_{sum\_max} \\ {i}_{sum\_min} \leq {i}_{u 2 s} + {i}_{v 2 s} + {i}_{w2s} - Δ {i}_{δ sum2} \leq {i}_{sum\_max}\end{matrix} \qquad ( 21 )$$

Herein, as shown in a next equation, in each set, the total error value Δiδsum of each set is calculated using a total error calculation function fδsum( ) which corresponds to a function which totals the error calculation functions fδ( ) of three-phase. That is, by referring the total error calculation function fδsum( ) of each set, the armature current detection unit 32 calculates the total error value Δiδsum of each set corresponding to the present detection value ifs of the field current. The total error calculation function fδsum( ) of each set is a function in which a relationship between the detection value ifs of the field current, and the total error value Δiδsum corresponding to a total value of the error components of the current detection values of three-phase which is generated by the magnetic flux of the rotor is a preliminarily set in each set, and it is stored in the storage apparatus 91. The total error calculation function fδsum( ) of each set is a map data, a polynomial, or the like.

$$\{ \begin{matrix}Δ {i}_{sum 1} = {f}_{δ sum 1} ( {i}_{fs} ) ≅ {f}_{δ u 1} ( {i}_{fs} ) + {f}_{δ v 1} ( {i}_{fs} ) + {f}_{δ w 1} ( {i}_{fs} ) \\ Δ {i}_{sum 2} = {f}_{δ sum 2} ( {i}_{fs} ) ≅ {f}_{δ u 2} ( {i}_{fs} ) + {f}_{δ v 2} ( {i}_{fs} ) + {f}_{δ w 2} ( {i}_{fs} )\end{matrix} \qquad ( 22 )$$

The armature current detection unit 32 may calculate the total error value Δiδsum of each set, by multiplying a preliminarily set total error calculation coefficient Kδsum of each set to the detection value ifs of the field current. The total error calculation coefficient Kδsum of each set corresponds to a total value of the error calculation coefficients Kδu, Kδv, Kδw of three-phase of each set in the equation (18).

In the present embodiment, a response time constant of the control system from the field current command value to the field current is larger than a response time constant of the control system from the armature current command to the armature current. Herein, the response time constant corresponds to a reciprocal of the cutoff frequency of the transfer function of the control system.

According to this configuration, since the field current changes slowly compared with the armature current, the correction accuracy can be secured even if the armature current is corrected based on the field current.

### 3. Embodiment 3

The current detection apparatus according to Embodiment 3 is explained with reference to drawings. Similar to Embodiment 1, the current detection apparatus is built into the AC rotary machine 1 and the controller 10. The explanation for constituent parts the same as those in Embodiment 1 will be omitted. The basic configuration of the AC rotary machine 1 and the controller 10 according to the present embodiment is the same as that of Embodiment 1. It is different from Embodiment 1 in the setting of inclination angle θt.

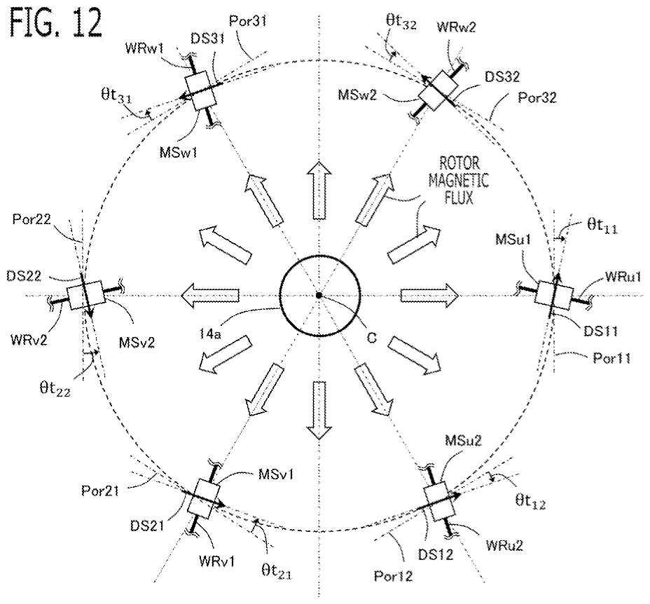

In the present embodiment, as shown in FIG. 12, in each set, the magnetic sensors MS of three-phase are disposed on the same circle centering on the axial center C. In the present embodiment, although all the magnetic sensors of first set and second set are disposed on the same circle, the radius of the same circle on which the magnetic sensors of three-phase of first set are disposed may be different from the radius of the same circle on which the magnetic sensors of three-phase of second set are disposed.

In the present embodiment, as shown in a next equation, in each set, the absolute values of the inclination angles θt of three-phase are equal with each other, and the magnetic sensor of positive side whose the inclination angle θt becomes positive, and the magnetic sensor of negative side whose the inclination angle θt becomes negative are provided.

$$\{ \begin{matrix}θ {t}_{11} = - θ {t}_{21} = θ {t}_{31} \\ θ {t}_{12} = - θ {t}_{22} = θ {t}_{32}\end{matrix} \qquad ( 23 )$$

In this case, as shown in a next equation, in each set, the absolute value of the detection error component δ of each phase is equal with each other, and the magnetic sensor of positive side whose the detection error component δ becomes positive, and the magnetic sensor of negative side whose the detection error component δ becomes negative are provided.

$$\{ \begin{matrix}{δ}_{u 1} = - {δ}_{v 1} = {δ}_{w 1} = {δ}_{1} \\ {δ}_{u 2} = - {δ}_{v 2} = {δ}_{w 2} = {δ}_{2}\end{matrix} \qquad ( 24 )$$

Accordingly, as shown in a next equation, in each set, a total of the current detection values of three-phase becomes a detection error component δ of one phase.

$$\{ \begin{matrix}{δ}_{u 1 s} = - {δ}_{v 1 s} + {δ}_{w 1 s} = {δ}_{1} \\ {δ}_{u 2 s} = - {δ}_{v 2 s} + {δ}_{w 2 s} = {δ}_{2}\end{matrix} \qquad ( 25 )$$

Then, as shown in an equation (26), in each set, by subtracting or adding a total of the current detection values of three-phase from the current detection value is of each phase, and calculating the current detection value iscr after correction of each phase, the error included in the current detection value can be reduced, and it can be brought close to the true current of each phase.

$$\{ \begin{matrix}{i}_{u 1 scr} = {i}_{u 1 s} + {K}_{cru 1} ( {i}_{u 1 s} + {i}_{v 1 s} + {i}_{w 1 s} ) = {i}_{u 1} , & {K}_{cru 1} = - 1 \\ {i}_{v 1 scr} = {i}_{v 1 s} + {K}_{crv 1} ( {i}_{u 1 s} + {i}_{v 1 s} + {i}_{w 1 s} ) = {i}_{v 1} , & {K}_{cru 1} = + 1 \\ {i}_{w 1 scr} = {i}_{w 1 s} + {K}_{crw 1} ( {i}_{u 1 s} + {i}_{v 1 s} + {i}_{w 1 s} ) = {i}_{w 1} , & {K}_{crw 1} = - 1 \\ {i}_{u 2 scr} = {i}_{u 2 s} + {K}_{cru 2} ( {i}_{u 2 s} + {i}_{v 2 s} + {i}_{w 2 s} ) = {i}_{u 2} , & {K}_{cru 2} = - 1 \\ {i}_{v 2 scr} = {i}_{v 2 s} + {K}_{crv 2} ( {i}_{u 2 s} + {i}_{v 2 s} + {i}_{w 2 s} ) = {i}_{v 2} , & {K}_{crv 2} = + 1 \\ {i}_{w 2 scr} = {i}_{w 2 s} + {K}_{crw 2} ( {i}_{u 2 s} + {i}_{v 2 s} + {i}_{w 2 s} ) = {i}_{w 2} , & {K}_{crw 2} = - 1\end{matrix} \qquad ( 26 )$$

Herein, as shown in the equation (11), the detection error component δ of each phase is proportional to the detection component Bs of the rotor flux density of each phase. Therefore, in each set, the magnetic sensors of three-phase may be disposed so that the absolute value of the detection component Bs of the rotor flux density of each phase becomes equal with each other; and in each set, the number of the magnetic sensor of positive side whose the inclination angle θt becomes positive, and the number of the magnetic sensor of negative side whose the inclination angle θt becomes negative may be greater than or equal to 1, and may be different number mutually. By disposing in this way, as shown in the equation (25), in each set, the total of the current detection values of three-phase becomes an integral multiple of the detection error component δ. In each set, the armature windings of greater than or equal to three-phase may be provided. Especially, in each set, if the armature windings of odd number-phase of greater than or equal to three are provided, the number of the magnetic sensor of positive side is easily differentiated from the number of the magnetic sensor of negative side.

Then, as shown in the equation (26), in each set, the armature current detection unit 32 corrects the current detection value of the armature winding of each phase, by a value obtained by multiplying a correction coefficient Kcr, which is set about each phase according to the number of the magnetic sensor of positive side and the number of the magnetic sensor of negative side, to the total of the current detection values of three-phase.

About a certain set, the total of the current detection values of each phase is J times (J is a positive or negative integer) of the detection error component δ. And, if J is a positive integer, and the total of the current detection values of each phase is a positive integer times of the detection error component δ included in the current detection value of a certain phase, the correction coefficient Kcr of that phase is set to a positive/negative inversing value (−1/J) of the reciprocal of J. If J is a positive integer, and the total of the current detection values of each phase is a negative integer times of the detection error component δ included in the current detection value of a certain phase, the correction coefficient Kcr of that phase is set a positive/negative inversing (−1/J) of the reciprocal of J. If J is a negative integer, and the total of the current detection values of each phase is a positive integer times of the detection error component δ included in the current detection value of a certain phase, the correction coefficient Kcr of that phase is set a positive/negative inversing (−1/J) of the reciprocal of J. If J is a negative integer, and the total of the current detection values of each phase is a positive integer times of the detection error component δ included in the current detection value of a certain phase, the correction coefficient Kcr of that phase is set to a positive/negative inversing value (−1/J) of the reciprocal of J.

As shown in a next equation, in each set, the absolute value of sine value of the inclination angle θt of each phase may become equal with each other. Then, in each set, the number of the magnetic sensor of positive side whose the inclination angle θt becomes positive, and the number of the magnetic sensor of negative side whose the inclination angle θt becomes negative may be greater than or equal to 1, and may be different number mutually.

$$\{ \begin{matrix}\vert sin θ {t}_{11} \vert = \vert sin θ {t}_{21} \vert = \vert sin θ {t}_{31} \vert \\ \vert sin θ {t}_{12} \vert = \vert sin θ {t}_{22} \vert = \vert sin θ {t}_{32} \vert\end{matrix} \qquad ( 27 )$$

In the present embodiment, even if the correction of the current detection value is not performed, as seen from the equation (6) and the equation (7), in the d-axis and q-axis current detection values ids, iqs of each set, the detection error component δ of each phase due to the magnetic flux of the rotor is canceled with each other, and can be reduced; and the d-axis and q-axis current detection values ids, iqs of each set can be brought close to the d-axis and q-axis true currents id, iq of each set. Accordingly, the control accuracy of output torque can be improved. Although the case where the magnetic sensor MS of each phase of each set is disposed on the same circle was explained, since the detection error component δ of the current of each phase of each set due to the magnetic flux of the rotor can be expressed using Br×sin θt like the equation (11), by making θt small on the radial-direction inner side where the magnetic flux is large, making θt large on the radial-direction outside where the magnetic flux is small, and making the absolute value of Br×sin θt equal, the absolute value of the detection error component δ of the current of each phase of each set due to the magnetic flux of the rotor can be made equal.

### 4. Embodiment 4

The current detection apparatus according to Embodiment 4 is explained with reference to drawings. Similar to Embodiment 1, the current detection apparatus is built into the AC rotary machine 1 and the controller 10. The explanation for constituent parts the same as those in Embodiment 1 will be omitted. The basic configuration of the AC rotary machine 1 and the controller 10 according to the present embodiment is the same as that of Embodiment 1. It is different from Embodiment 1 in the setting of inclination angle θt.

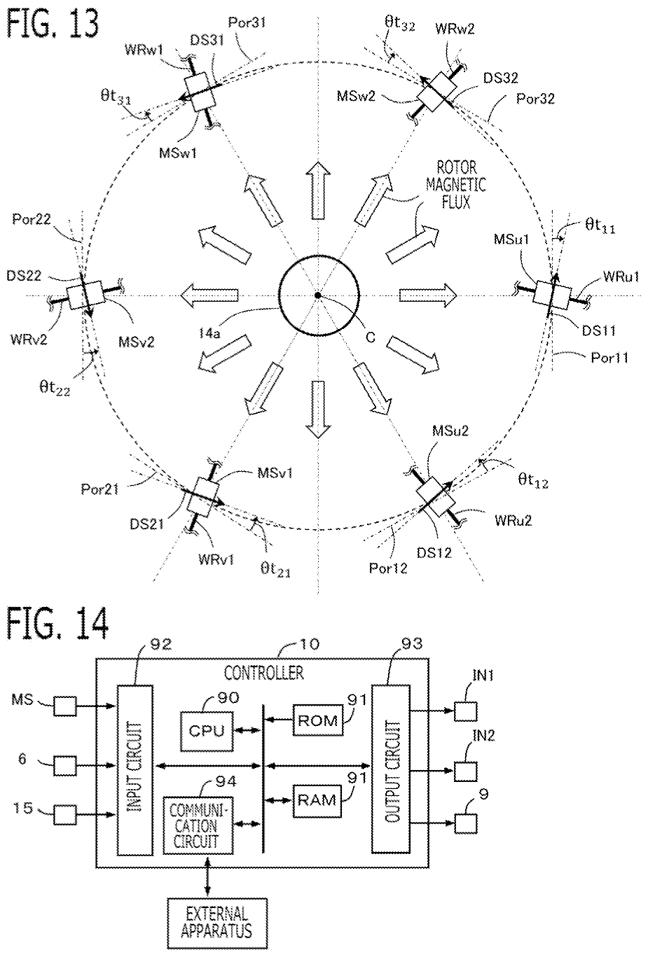

In the present embodiment, as shown in FIG. 13, in each set, the magnetic sensors MS of three-phase are disposed on the same circle centering on the axial center C. In the present embodiment, although all the magnetic sensors of first set and second set are disposed on the same circle, the radius of the same circle on which the magnetic sensors of three-phase of first set are disposed may be different from the radius of the same circle on which the magnetic sensors of three-phase of second set are disposed.

In the present embodiment, as shown in a next equation, in each set, the absolute values of the inclination angles θt of three-phase are equal with each other, and the magnetic sensor of positive side whose the inclination angle θt becomes positive, and the magnetic sensor of negative side whose the inclination angle θt becomes negative are provided. The number of the magnetic sensor of negative side of first set (in this example, one) and the number of the magnetic sensor of positive side of second set (in this example, one) are equal. On the other hand, the number of the magnetic sensor of positive side of first set (in this example, two) and the number of the magnetic sensor of negative side of second set (in this example, two) are equal.

$$\{ \begin{matrix}θ {t}_{11} = - θ {t}_{21} = θ {t}_{31} \\ - θ {t}_{12} = - θ {t}_{22} = θ {t}_{32}\end{matrix} \qquad ( 28 )$$

In this case, as shown in a next equation, in each set, the absolute values of the detection error components δ of three-phase are equal with each other, and the magnetic sensor of positive side whose the detection error component δ becomes positive, and the magnetic sensor of negative side whose the detection error component δ becomes negative are provided.

$$\{ \begin{matrix}{δ}_{u 1} = - {δ}_{v 1} = {δ}_{w 1} = {δ}_{1} \\ - {δ}_{u 2} = - {δ}_{v 2} = {δ}_{w 2} = {δ}_{2}\end{matrix} \qquad ( 29 )$$

Accordingly, as shown in a next equation, a total of the current detection values of three-phase of each set becomes the detection error component δ of positive or negative one phase. The total error component δ1 of first set corresponding to the total of the current detection values of three-phase of first set, and the total error component −δ2 of second set corresponding to the total of the current detection values of three-phase of second set become different positive and negative signs with each other.

$$\{ \begin{matrix}{i}_{u 1 s} + {i}_{v 1 s} + {i}_{w 1 s} = {δ}_{1} \\ {i}_{u 2 s} + {i}_{v 2 s} + {i}_{w 2 s} = - {δ}_{2}\end{matrix} \qquad ( 30 )$$

At this time, as shown in a next equation, the total of the current detection values of all sets and all phases become δ1−δ2.

iᵤ₁ₛ+iᵥ₁ₛ+i_{w1s}+iᵤ₂ₛ+iᵥ₂ₛ+i_{w2s}=δ₁−δ₂ (31)

Herein, since δ1 and δ2 are same signs, a next equation is established.

$$\{ \begin{matrix}\vert {i}_{u 1 s} + {i}_{v 1 s} + {i}_{w 1 s} + {i}_{u 2 s} + {i}_{v 2 s} + {i}_{w 2 s} \vert < \vert {i}_{u 1 s} + {i}_{v 1 s} + {i}_{w 1 s} \vert \\ \vert {i}_{u 1 s} + {i}_{v 1 s} + {i}_{w 1 s} + {i}_{u 2 s} + {i}_{v 2 s} + {i}_{w 2 s} \vert < \vert {i}_{u 2 s} + {i}_{v 2 s} + {i}_{w 2 s} \vert\end{matrix} \qquad ( 32 )$$

δ1 and δ2 change according to the field current. Compared with a change width of the total of the current detection values of each set due to a change of field current, a change width of the total of the current detection values of all sets and all phases can be made small. Accordingly, if the abnormality of the magnetic sensor is detected by the total current, the accuracy of abnormality detecting can be improved by utilizing the total of the current detection values of all sets and all phases.

As shown in the equation (32), if an all total error obtained totaling, about all sets and all phases, the detection error components δ due to the rotor magnetic flux becomes smaller than a total error of each set obtained totaling, about all phases of each set, the detection error components δ, the accuracy of abnormality detecting can be improved by utilizing the total of the current detection values of all sets and all the phase.

Especially, if the equation (33) is satisfied, the all total error becomes 0, and the equation (34) is established. Accordingly, the total of the current detection values of all sets and all the phase can be kept at 0, irrespective of the change of field current. That is to say, even if the total of the current detection values of all the phase does not become 0 in each set, by using the total of the current detection values of all sets and all phases, the magnetic flux of the rotor can be canceled with each other, and it can be made 0.

δ₁+δ₂ (33)

iᵤ₁ₛ+iᵥ₁ₛ+i_{w1s}+iᵤ₂ₛ+iᵥ₂ₛ+i_{w2s}=0 (34)

Then, as shown in next equation, the armature current detection unit 32 determines that abnormality occurred, when the total of the current detection values of all sets and all the phase exceeds a preliminarily set determination range.

i_{sum_min}≤iᵤ₁ₛ+iᵥ₁ₛ+i_{w1s}+iᵤ₂ₛ+iᵥ₂ₛ+i_{w2s}·i_{sum_max} (35)

The armature current detection unit 32 determines that it is normal when the equation (31) is established, and determines that it is abnormal when the equation (31) is not established. Herein, a determination lower limit value isum_min and a determination upper limit value isum_max are preliminarily set considering the variation width due to variation factors, such as the temperature characteristic of the magnetic sensor, and the aging change.

Even in the present embodiment, similar to Embodiment 3, in each set, the armature current detection unit 32 may correct the current detection value of the armature winding of each phase, by a value obtained by multiplying a correction coefficient Kcr, which is set about each phase according to the number of the magnetic sensor of positive side and the number of the magnetic sensor of negative side, to the total of the current detection values of three-phase.

Even if the correction of the current detection value is not performed, as seen from the equation (6) and the equation (7), in the d-axis and q-axis current detection values ids, iqs of each set, the detection error component δ of each phase due to the magnetic flux of the rotor can be canceled with each other, and it can be reduced. And, the d-axis and q-axis current detection values ids, iqs of each set can be brought close to the d-axis and q-axis true currents id, iq of each set. Accordingly, the control accuracy of output torque can be improved.

Each magnetic sensor MS may be disposed opposite to a connection line which is provided in the series circuit of each phase of the positive electrode side switching device and the negative electrode side switching device in the inverter of each set. And, the inverter of each set may be disposed at a place where the magnetic flux of the radial direction emitted from the rotor crosses.

Although the present disclosure is described above in terms of various exemplary embodiments and implementations, it should be understood that the various features, aspects and functionality described in one or more of the individual embodiments are not limited in their applicability to the particular embodiment with which they are described, but instead can be applied, alone or in various combinations to one or more of the embodiments. It is therefore understood that numerous modifications which have not been exemplified can be devised without departing from the scope of the present disclosure. For example, at least one of the constituent components may be modified, added, or eliminated. At least one of the constituent components mentioned in at least one of the preferred embodiments may be selected and combined with the constituent components mentioned in another preferred embodiment.

What is claimed is:

1. A current detection apparatus of an AC rotary machine which is provided with a rotor and a stator having m sets of n-phase armature windings (m is an integer greater than or equal to one, and n is an integer greater than or equal to 3), the current detection apparatus comprising:
m sets of n-phase magnetic sensors each of which is disposed opposite to a connection line of each phase of each set supplying current to the armature winding of each phase of each set; and
an armature current detector which detects a current which flows into the armature winding of each phase of each set, based on an output signal of the magnetic sensor of each phase of each set,
wherein the magnetic sensor of each phase of each set is disposed at a position where a magnetic flux radially emitted from the rotor in a radial direction crosses, and
in each set, the magnetic sensors of n-phase are disposed so that an absolute value of a detection component of a rotor flux density which is a component of flux density of the rotor detected by the magnetic sensor of each phase become equal with each other.

2. The current detection apparatus according to claim 1,
wherein in each set, the magnetic sensors of n-phase are disposed on the same circle centering on an axial center.

3. The current detection apparatus according to claim 2,
wherein in each set, an absolute value of sine value of an inclination angle of a magnetic flux detecting direction of the magnetic sensor of each phase with respect to a radial orthogonal plane which is a plane orthogonal to a radial direction passing through the magnetic sensor of each phase is equal with each other.

4. The current detection apparatus according to claim 3,
wherein the absolute value of sine value of each phase of each set is less than 1/√2.

5. The current detection apparatus according to claim 3,
wherein the absolute value of sine value of each phase of each set is less than 1/5.

6. The current detection apparatus according to claim 1,
wherein about an inclination angle of a magnetic flux detecting direction of the magnetic sensor of each phase with respect to a radial orthogonal plane which is a plane orthogonal to a radial direction passing through the magnetic sensor of each phase,
the magnetic sensor whose the inclination angle becomes positive is defined as the magnetic sensor of positive side,
the magnetic sensor whose the inclination angle becomes negative is defined as the magnetic sensor of negative side, and
in each set, a number of the magnetic sensor of positive side and a number of the magnetic sensor of negative side are greater than or equal to one, and are different number mutually.

7. The current detection apparatus according to claim 6,
wherein n is an odd number greater than or equal to 3.

8. The current detection apparatus according to claim 6,
wherein in each set, the armature current detector corrects a current detection value of the armature winding of each phase, by a value obtained by multiplying a total of the current detection values of the armature windings of n-phase and a correction coefficient which is set about each phase according to the number of the magnetic sensor of positive side and the number of the magnetic sensor of negative side.

9. The current detection apparatus according to claim 6,
wherein m is 2, the magnetic sensors of n-phase of first set and the magnetic sensors of n-phase of second set are disposed on the same circle centering on an axial center,
the number of the magnetic sensor of positive side of first set and the number of the magnetic sensor of negative side of second set are equal with each other, and
the number of the magnetic sensor of negative side of first set and the number of the magnetic sensor of positive side of second set are equal with each other.

10. The current detection apparatus according to claim 1,
wherein in each set, the magnetic sensors of n-phase are disposed so that the detection component of the rotor flux density which is a component of flux density of the rotor detected by the magnetic sensor of each phase become equal with each other.

11. The current detection apparatus according to claim 10,
wherein in each set, an inclination angle of a magnetic flux detecting direction of the magnetic sensor of each phase with respect to a radial orthogonal plane which is a plane orthogonal to a radial direction passing through the magnetic sensor of each phase is equal with each other.

12. The current detection apparatus according to claim 1,
wherein an all total error becomes smaller than a total error of each set,
wherein the all total error is an error obtained by totaling, about all sets and all phases, error components each of which is included in the current detection value of the armature winding and is generated by the magnetic flux of the rotor which crosses the magnetic sensor, and
wherein the total error of each set is an error obtained by totaling, about all phases, the error components.

13. The current detection apparatus according to claim 12,
wherein the all total error is 0.

14. The current detection apparatus according to claim 12,
wherein the armature current detector determines that abnormality occurred, when an all total current detection value that totals the current detection values of the armature windings of all sets and all phases exceeds a preliminarily set determination range.

15. The current detection apparatus according to claim 1,
wherein the rotor is provided with a field winding.

16. A current detection apparatus of an AC rotary machine which is provided with a rotor having a field winding and a stator having m sets of n-phase armature windings (m is an integer greater than or equal to one, and n is an integer greater than or equal to 2), the current detection apparatus comprising:
m sets of n-phase magnetic sensors each of which is disposed opposite to a current path flowing current of the armature winding of each phase of each set; and
an armature current detector which detects a current which flows into the armature winding of each phase of each set, based on an output signal of the magnetic sensor of each phase of each set,
wherein the magnetic sensor of each phase of each set is disposed at a position where a magnetic flux radially emitted from the rotor in a radial direction crosses,
wherein the armature current detector, about each phase of each set, calculates a current error value corresponding to an error component of the current detection value which is generated by the magnetic flux of the rotor which crosses the magnetic sensor, based on a field current which flows through the field winding; and
corrects the current detection value of each phase of each set by the current error value of each phase of each set, and
wherein about each phase of each set, by referring to an error calculation function in which a relationship between the field current and the current error value is preliminarily set, the armature current detector calculates the current error value corresponding to the present field current.

17. The current detection apparatus according to claim 16,
wherein the error calculation function of each phase of each set is a function for calculating the current error value of each phase of each set by multiplying the field current to a preliminarily set error calculation coefficient of each phase of each set.

18. The current detection apparatus according to claim 15,
wherein the armature current detector, in each set, calculates a total error value corresponding to a total value of the error components of the current detection values of n-phase each of which is generated by the magnetic flux of the rotor, based on the field current which flows through the field winding; and
in each set, determines that abnormality occurred, when a value obtained by subtracting the total error value from a total value of the current detection values of n-phase exceeds a preliminarily set determination range, and
wherein in each set, by referring to a total error calculation function in which a relationship between the field current and the total error value is preliminarily set, the armature current detector calculates the total error value corresponding to the present field current.

19. The current detection apparatus according to claim 18,
wherein the total error calculation function of each set is a function for calculating the total error value of each set by multiplying the field current to a preliminarily set total error calculation coefficient of each set.

20. The current detection apparatus according to claim 1,
wherein the rotor is a Lundell type rotor in which the field winding is wound concentrically centering on an axial center, and an axial direction one side part of the rotor becomes N pole or S pole, and
wherein the magnetic sensor of each phase of each set is disposed on an axial direction one side of the rotor, and the magnetic flux radially emitted in the radial direction from the axial direction one side part of the rotor crosses the magnetic sensor of each phase of each set.

21. A controller for AC rotary machine provided with the current detection apparatus according to claim 15 comprising:
an armature current controller that calculates an armature current command value which is a current command value of the armature winding, calculates an armature voltage command value based on the armature current command value and the current detection value of the armature winding detected by the current detection apparatus, and applies voltage to the armature winding by controlling on/off a switching device which an inverter has based on the armature voltage command value, and
a field current controller that calculates a field current command value which is a current command value of the field winding, and applies voltage to the field winding by controlling on/off a switching device which a converter has based on the field current command value,
wherein a response time constant of a control system from the field current command value to a field current which flows through the field winding is larger than a response time constant of a control system from the armature current command value to an armature winding current.
